(19) United States
(12) Patent Application Publication
(10) Pub. No.: US 2026/0146314 A1
(43) Pub. Date: May 28, 2026

(54) METHOD FOR THE DEPOSITION OF GROUP IIIA METAL NITRIDE FILMS

(71) Applicant: AGC GLASS EUROPE, Louvain-la-Neuve (BE)

(72) Inventor: Gerard RUITENBERG, Gosselies (BE)

(73) Assignee: AGC GLASS EUROPE, Louvain-la-Neuve (BE)

(21) Appl. No.: 19/119,858

(22) PCT Filed: Oct. 26, 2023
(86) PCT No.: PCT/EP2023/080003

§ 371 Date: Apr. 10, 2025

(30) Foreign Application Priority Data
Nov. 8, 2022 (EP) 22206203.6

(51) Int. Cl. C23C 14/35; C23C 14/06; C23C 14/08

(52) U.S. Cl. CPC C23C 14/35; C23C 14/0617; C23C 14/086

(57) ABSTRACT

A process for depositing group IIIA metal nitride layers with preferred (002) orientation by providing a substrate, depositing by magnetron sputtering a seed layer of ZnO on the substrate, and depositing by magnetron sputtering a first group IIIA metal nitride layer directly on the seed layer. Additionally, a coated substrate made in sequence, starting from the substrate surface, a seed layer of ZnO and a first group IIIA metal nitride layer, wherein the first group IIIA metal nitride layer has a preferred crystalline orientation (002) and uses a seed layer of ZnO to increase the crystallinity of a first group IIIA metal nitride layer deposited directly on said seed layer.

### TECHNICAL FIELD

The present invention relates to a process for the deposition by magnetron sputtering of group IIIA metal nitride films that exhibit preferred crystalline orientation.

Group IIIA metal nitride films, in particular having a wide bandgap are of use in a variety of applications, in particular in the development and fabrication of a variety of semiconductor devices.

### BACKGROUND ART

The compound semiconductors of gallium nitride (GaN), aluminum nitride (AlN), and indium nitride (InN) are excellent materials for bandgap engineering, because they form a continuous range of solid solutions and superlattices with direct room-temperature band gaps ranging from 0.65 eV for InN, to 3.4 eV for GaN, to 6.2 eV for AlN. Recently a great deal of interest has been shown especially in the InGaN due to its worldwide demand for high-brightness blue and green light-emitting diodes (LEDs) and laser diodes (LDs).

Group IIIA metal nitride films can be produced via various methods including metal organic chemical vapor deposition (MOCVD), molecular beam epitaxy (MBE), metal organic vapor phase epitaxy (MOVPE), electron cyclotron resonance dual-ion beam sputtering, and pulsed laser ablation. However, these methods are expensive and/or slow and high processing temperatures are generally required. Also, phase separation is usually observed for In_{X}Al_{1-X}N by MOCVD, for x>0.32 and requires a chemical reaction to take place, which makes it difficult to form non-equilibrium compositions.

Sputtering has been used to deposit group IIIA metal nitride films on a variety of substrates, however a high degree of preferred (002) orientation is typically only obtained when crystalline substrates are used. Such substrates are expensive an available only in limited sizes.

### SUMMARY OF INVENTION

The present inventors have made an effort to overcome the drawbacks mentioned above and develop an economical process for preparing group IIIA metal nitride films, in particular at temperatures that reduce or avoid atomic diffusion, for example between different layers, and possible quality decrease of the interfaces, and have discovered that group IIIA metal nitride films that exhibit preferred crystalline orientation, can be prepared by magnetron sputtering on zinc oxide seed layers deposited by magnetron sputtering.

The present invention concerns in an embodiment a process for depositing group IIIA metal nitride films with preferred (002) orientation comprising
a. providing a substrate;
b. depositing by magnetron sputtering a seed layer comprising ZnO on the substrate;
c. depositing by magnetron sputtering first group IIIA metal nitride film.

The inventors have found that the resulting first group IIIA metal nitride films or layers present an excellent degree of (002) crystalline orientation, whether the substrate is crystalline or not. In particular, a high degree of (002) crystalline orientation is obtained even on substrates, such as glass, plastics or metals, on which directly deposited first group IIIA metal nitride layers deposited by magnetron sputtering present barely any degree of (002) crystal orientation.

Magnetron sputtering is particularly suited for high deposition rates and large substrate surfaces and does not require substrate heating. In magnetron sputtering, substrates may be static during deposition, but may advantageously move during deposition. Substrates may even be continuous bands of for example metal, with a width of more than 3 m. Substrates may also be individual substrate sheets, for example of 3.21 m×6.00 m or more. Furthermore, compared to chemical vapor deposition for example, the layers resulting from magnetron sputtering provide a smoother surface and can be deposited at room temperature, whereas chemical vapor deposition requires high temperatures up to 800° C. There is also less risk of including unwanted pollution in the coating when magnetron sputtering is used as CVD methods use i.a. carbon containing precursors and may lead to carbon being present in the coating and perturbing the crystalline structure of the coating. Atomic layer deposition is slow and generally requires high temperatures for obtaining good crystal orientation, which may have many drawbacks in a coating process.

### BRIEF DESCRIPTION OF THE DRAWINGS

FIGS. 1 and 2 show XRD plots of different aluminum nitride (AlN) coated substrates, according to embodiments of the present invention.

### DETAILED DESCRIPTION OF EMBODIMENTS

In a preferred embodiment of the present invention the first group IIIA metal nitride layer is deposited directly on the seed layer, meaning that no layers are deposited after the seed layer has been deposited and before the first group IIIA metal nitride layer has been deposited.

In an embodiment of the present invention, the seed layer comprises or essentially consists of optionally doped ZnO.

In an embodiment of the present invention, the seed layer has a thickness of at least 0.3 nm, 0.5 nm, 1 nm, or 2 nm.

In an embodiment of the present invention, the seed layer has a thickness of up to 5 nm, 10 nm, 20 nm, 30 nm, 40 nm, 50 nm, 75 nm, 100 nm, 150 nm, 200 nm or 250 nm.

When the seed layer is too thin it has little impact on the crystallinity of the subsequently deposited first group IIIA metal nitride layer. A significant effect on the crystallinity of the subsequently deposited first group IIIA metal nitride layer is already observed at a seed layer thickness below 10 nm. With increasing seed layer this effect may increase, however the seed layer surface roughness also increases, which may be detrimental for some applications.

All thicknesses mentioned here within are geometrical or physical thicknesses, unless otherwise noted.

In an embodiment of the present invention, the seed layer comprises ZnO and up to 10 at % of a dopant selected from Al, Ga, B, In. In an alternate embodiment, the ZnO seed layer may be free of dopant. Dopants may be added for example to provide electrical conductivity to the seed layer.

In an embodiment of the present invention, the seed layer is deposited by magnetron sputtering from a sputtering target selected from
a. an, optionally doped, Zn metal target for example in an atmosphere comprising Ar and O₂, for example from 40 to 80% O₂ in Ar, and
b. a ceramic target comprising ZnO, optionally doped, for example in a 100% Ar atmosphere

The optional target dopants may be selected from Al, Ga, B, and In.

Here within the percentages in gas compositions are molar percentages.

According to an embodiment, the present invention further comprises, after depositing the first group IIIA metal nitride film, depositing by magnetron sputtering a second group IIIA metal nitride film directly on the first group IIIA metal nitride layer, the second group IIIA metal nitride being different from the first group IIIA metal nitride film.

According to an advantageous embodiment of the present invention, depositing of the seed layer and/or of the first group IIIA metal nitride layer and/or of the second group IIIA metal nitride film is performed without additional heating of the substrate, prior to or during the deposition of the seed layer and/or first group IIIA metal nitride layer and or second group IIIA metal layer. This means that the substrate is not intentionally heated and is introduced into the coating process at room temperature. Generally the temperature of the substrate may be kept at a temperature of between 20° C. and 150° C., during the deposition of the seed layer and/or the first group IIIA metal nitride layer. During the deposition of these layers, the substrate temperature is preferably kept below 150° C., below 100° C., or even below 50° C. Lower temperatures lead to lower diffusion of substrate and/or layer components and thus to less defects in the final product.

According to an embodiment of the present invention the first and second group IIIA metal nitrides are selected from indium nitride, aluminum nitride, gallium nitride, boron nitride, or from a mixed nitride of two or more of indium nitride, aluminum nitride, gallium nitride, and boron nitride.

In an advantageous embodiment of the present invention the first group IIIA metal nitride comprises mixed nitride of indium and aluminum and the second group IIIA metal nitride comprises gallium nitride. It was found that for the resulting gallium nitride layer particularly good crystallinity could be obtained by fine adjustments of the mixed nitride of indium and aluminum.

The first group IIIA metal nitride film thicknesses may be adapted depending on the application they are used for. Thicknesses in the range from 10 nm to 100 nm, or from 20 nm to 90 nm, may for example be useful in LED applications. Thicknesses in the range from 1 μm to 3 μm, may for example be useful in photovoltaic applications. Thicknesses in the range from 10 nm to 3 μm, may for example be useful when a second group IIIA metal nitride layer is subsequently deposited.

According to an embodiment of the present invention the first group IIIA metal nitride layer has a thickness of at least 10 nm, or at least 20 nm, or least 30 nm.

According to an embodiment of the present invention the first group IIIA metal nitride layer has a thickness of up to 1 μm, or up to 2 μm, or up to 3 μm.

In a mixed first group IIIA metal nitride layer, the ratio of components is adjusted for example to reach a certain bandgap. The atomic metal percentage may be adjusted in a very wide range, in particular from 1 to 99% of any one of B, In, Al and Ga.

The first group IIIA metal nitride layers of the present invention may have a bandgap ranging from 0.65 eV to 6.2 eV.

Preferably the first and/or group IIIA metal nitride layer is stoichiometric, with a metal to nitrogen ratio of 1. However, the metal to nitrogen atomic ratio may vary for example from 0.8 to 1.2, alternately from 0.9 to 1.1.

The second group IIIA metal nitride film thicknesses may be adapted depending on the application they are used for. Thicknesses in the range from 10 nm to 100 nm, or from 20 nm to 90 nm, may for example be useful in LED applications. Thicknesses in the range from 1 μm to 3 μm, may for example be useful in photovoltaic applications.

According to an embodiment of the present invention the second group IIIA metal nitride layer has a thickness of at least 10 nm, or at least 20 nm, or least 30 nm.

According to an embodiment of the present invention the second group IIIA metal nitride layer has a thickness of up to 1 μm, or up to 2 μm, or up to 3 μm.

In a mixed second group IIIA metal nitride layer, the ratio of components is adjusted for example to reach a certain bandgap. The atomic metal percentage may be adjusted in a very wide range, in particular from 1 to 99% of any one of B, In, Al and Ga.

The second group IIIA metal nitride layer of the present invention may have a bandgap ranging from 0.65 eV to 6.2 eV.

Preferably the second group IIIA metal nitride layer is stoichiometric, with a metal to nitrogen ratio of 1. However, the metal to nitrogen atomic ratio may vary for example from 0.8 to 1.2, alternately from 0.9 to 1.1.

According to an embodiment of the present invention the first and second group IIIA metal nitride layers are deposited by magnetron sputtering from one or more metallic sputtering targets comprising indium, aluminum, gallium and/or boron. One or more pure metal and/or metal alloy targets may be used to reach the desired metal nitride composition. Sputtering with two or more targets of different composition is generally known as co-sputtering.

As is well known, sputtering is performed under vacuum. Typically the pressure during deposition is kept at values ranging from 0.1 to 99 mTorr (10⁻³ Torr), that is 0.13 mbar to 132 mbar, preferably from 0.5 to 15 mTorr, that is 6.66 mbar to 20.0 mbar.

According to an embodiment, sputtering deposition of first and/or second group IIIA metal nitride layer is performed in an atmosphere of N₂ or of a mixture of Ar and N₂, comprising between 10 and 100% of N₂. Preferably, the amount of N2 is adjusted so as to obtain a stoichiometric first and/or second group IIIA metal nitride, at the best possible deposition rate. Higher deposition rates are obtained with mixtures of Ar and N₂ comprising between 10 and 50%, preferably between 20 and 40% N₂. Alternately, for example to promote good stoichiometry, pure N₂ or a mixture of Ar and N₂ comprising between 50 and 100% of N₂, preferably between 70 and 100% of N₂, even more preferably between 80 and 100% of N₂, most preferably between 90% and 100% N₂ may be used.

It should be noted that while not intentionally added, the resulting metal nitride layers may comprise trace amounts of other elements stemming for example from impurities in the sputtering targets.

Furthermore, while not intentionally added, up to 10 at % of oxygen may be found in the first and/or second group IIIA metal nitride layers, stemming for example from water desorbing from the walls of the coating line. Preferably, the oxygen content of these nitride films is less than 5 at %, even less than 2 at %.

According to an embodiment of the present invention the substrate may be provided as a substrate sheet or substrate wafer.

The substrate material may be crystalline or not, i.e. amorphous. It is a particular advantage of the present invention that a crystalline substrate is not required to obtain a high degree of preferred crystalline orientation in the first group IIIA metal nitride layer. In particular the substrate may be selected from crystalline Ge, crystalline Si, sapphire, glass, metal e.g. aluminum, copper, steel, and polymer.

A glass substrate material according to the invention is made of glass whose matrix composition is not particularly limited and may thus belongs to different glass categories. The glass may be a soda-lime-silicate glass, an alumino-silicate glass, an alkali-free glass, a boro-silicate glass, etc. In the glass compositions below, all component percentages are weight percentages.

According to an embodiment of the invention, the glass substrate material has a composition comprising, in a content expressed in percentages of the total weight of the glass:

| | |
|---|---|
| SiO₂ | 55-85% |
| Al₂O₃ | 0-30% |
| B₂O₃ | 0-20% |
| Na₂O | 0-25% |
| CaO | 0-20% |
| MgO | 0-15% |
| K₂O | 0-20% |
| BaO | 0-20%. |

In a preferred manner, the glass substrate material has a composition comprising, in a content expressed in percentages of the total weight of the glass:

| | |
|---|---|
| SiO₂ | 55-78% |
| Al₂O₃ | 0-18% |
| B₂O₃ | 0-18% |
| Na₂O | 5-20% |
| CaO | 0-10% |
| MgO | 0-10% |
| K₂O | 0-10% |
| BaO | 0-5%. |

In a more preferred manner, the glass substrate material has a composition comprising, in a content expressed in percentages of the total weight of the glass:

| | |
|---|---|
| SiO₂ | 65-78% |
| Al₂O₃ | 0-6% |
| B₂O₃ | 0-4% |
| CaO | 0-10% |
| MgO | 0-10% |
| Na₂O | 5-20% |
| K₂O | 0-10% |
| BaO | 0-5%. |

Such a soda-lime-type base glass composition has the advantages to be inexpensive even if it is less mechanically resistant as such.

Ideally, according to this last embodiment, the glass composition does not comprise B₂O₃ (meaning that it is not intentionally added, but could be present as undesired impurities in very low amounts).

In an alternative manner, the glass substrate material has a composition comprising, in a content expressed in percentages of the total weight of the glass:

| | |
|---|---|
| SiO₂ | 55-70% |
| Al₂O₃ | 6-18% |
| B₂O₃ | 0-4% |
| CaO | 0-10% |
| MgO | 0-10% |
| Na₂O | 5-20% |
| K₂O | 0-10% |
| BaO | 0-5%. |

Such alumino-silicate-type base glass compositions have the advantage to be more mechanically resistant but it is more expensive than soda-lime glass.

Ideally, according to this last embodiment, the glass composition does not comprise B₂O₃ (meaning that it is not intentionally added, but could be present as undesired impurities in very low amounts).

According to an advantageous embodiment of the invention, combinable with previous embodiments on base glass composition, the glass substrate material has a composition comprising a total iron (expressed in terms of Fe₂O₃) content ranging from 0.002 to 0.06%. A total iron (expressed in the form of Fe₂O₃) content of less than or equal to 0.06% makes it possible to obtain a glass substrate material with almost no visible coloration and allowing a high degree of flexibility in aesthetic designs (for example, getting no distortion when white silk printing of some glass elements of smartphones). The minimum value makes it possible not to be excessively damaging to the cost of the glass as such, low iron values often require expensive, very pure, starting materials and also purification of these. Preferably, the composition comprises a total iron (expressed in the form of Fe₂O₃) content ranging from 0.002 to 0.04%. More preferably, the composition comprises a total iron (expressed in the form of Fe₂O₃) content ranging from 0.002 to 0.02%. In the most preferred embodiment, the composition comprises a total iron (expressed in the form of Fe₂O₃) content ranging from 0.002 to 0.015%.

According to another embodiment of the invention, in combination with previous embodiments on Fe₂O₃ content, the glass has a composition comprising chromium in a content such as: 0.0001%≤Cr₂O₃≤0.06%, expressed in percentages of the total weight of glass. Preferably, the glass has a composition comprising chromium in a content such as: 0.002%≤Cr₂O₃≤0.06%. This chromium content allows getting a glass with a higher IR transmission.

According to a preferred embodiment, the glass substrate material of the invention is a float glass sheet. The term “float glass sheet” is understood to mean a glass sheet formed by the float process, which consists in pouring the molten glass onto a bath of molten tin, under reducing conditions. A float glass sheet comprises, in a known way, a “tin face”, that is to say a face enriched in tin in the body of the glass close to the surface of the sheet. The term “enrichment in tin” is understood to mean an increase in the concentration of tin with respect to the composition of the glass at the core, which may or may not be substantially zero (devoid of tin). Therefore, a float glass sheet can be easily distinguished from sheets obtained by other glassmaking processes, in particular by the tin oxide content which may be measured, for example, by electronic microprobe to a depth of ˜10 μm.

According to another preferred embodiment, the glass substrate material of the invention is a glass sheet formed by a slot draw process or by a fusion process, in particular the overflow downdraw fusion process. These processes, in particular the fusion process produces glass sheets whose surfaces may reach superior flatness and smoothness necessary in some applications, but they are also more expensive than the float process for large scale glass production.

The glass substrate according to the invention may have a thickness of from 0.5 to 25 mm. Depending on the intended application, the glass substrate may have a thickness of from 1 to 6 mm, or from 2 to 4 mm.

According to an embodiment of the present invention, the process comprises before depositing the seed layer, depositing one or more layers. The seed layer is not necessarily deposited directly on the substrate. These one or more layers may be deposited by any known deposition method, for example by magnetron sputtering, plasma enhanced chemical vapor deposition, chemical vapor deposition, atomic layer deposition, molecular vapor phase epitaxy. These one or more layers may have different functions, for example provide a clean and smooth surface for the deposition of the seed layer, conduct electricity, block migration of any constituents of the substrate or any layer.

According to an embodiment of the present invention, a bottom layer that is preferably amorphous is deposited on the substrate, before depositing the seed layer. Thereby any possible crystallinity of the substrate is prevented from influencing the growth of subsequent layers. In particular the bottom layer may be in direct contact with the substrate. In particular, the seed layer may be deposited directly on an amorphous layer. Example amorphous layers are Zn₂SnO₄, Si₃N₄, SiO₂, titanium oxide, nitride of zirconium and silicon, oxide of titanium and zirconium.

According to an embodiment of the present invention, the process comprises, after the deposition of the first and/or second group IIIA metal nitride layers, a heating step comprising heating the substrate for example under vacuum or in a nitrogen comprising atmosphere, in particular so as to further increase the preferred crystalline orientation of the first and/or second group IIIA metal nitride layers. This temperature is preferably at least 100° C. This temperature may reach up to the softening point of the substrate. This temperature may be comprised between 100° C. and 950° C.

According to an advantageous embodiment of the present invention, the process comprises no heating step after the deposition of the first and/or second group IIIA metal nitride layer. The crystallinity of the first and/or second group IIIA metal nitride may be sufficient for the subsequent use of the first and/or second group IIIA metal nitride layer.

Mention deposition rates vs molecular beam epitaxy, The inventors found that first group IIIA metal nitride layers, in particular aluminum nitride layers, could be deposited at static deposition rates of up to at least 40 nm/min while MOCVD static deposition rates seem not to exceed 20 nm/min.

The present invention further concerns a coated substrate comprising in sequence, starting from the substrate surface, a seed layer comprising ZnO and a first group IIIA metal nitride layer, wherein the first group IIIA metal nitride layer has a preferred crystalline orientation (002). Advantageously, the first group IIIA metal nitride layer is in direct contact with the seed layer.

The present invention further concerns a coated substrate comprising in sequence, starting from the substrate surface, a seed layer comprising ZnO and a first group IIIA metal nitride layer and a second group IIIA metal nitride layer, wherein the composition of the second group IIIA metal nitride layer is different from the first group IIIA metal nitride layer, and wherein the first group IIIA metal nitride layer has a preferred crystalline orientation (002) and the second group IIIA metal nitride layer also has a preferred crystalline orientation (002). Advantageously, the first group IIIA metal nitride layer is in direct contact with the seed layer and with the second group IIIA metal nitride layer.

According to embodiments of the present invention the coated substrate may be deposited using the process of the present invention.

In the coated substrates of the present invention, the substrate may be selected from the substrates mentioned hereinabove for the process of the present invention.

In the coated substrates of the present invention, the seed layer composition may be selected from the seed layer compositions mentioned hereinabove for the process of the present invention.

In the coated substrates of the present invention, the first and second group IIIA metal nitride may be selected from the group IIIA metal nitrides mentioned hereinabove for the process of the present invention.

The present invention further concerns the use of a seed layer comprising ZnO, in particular deposited by magnetron sputtering, in particular by magnetron sputtering to increase the crystallinity of a first group IIIA metal nitride layer deposited directly on the seed layer, in particular by magnetron sputtering.

The present invention further concerns the use of a seed layer comprising ZnO, in particular deposited by magnetron sputtering to increase the crystallinity, in particular the crystalline orientation (002), of a first group IIIA metal nitride layer deposited directly on the seed layer, in particular by magnetron sputtering and to increase the crystallinity, in particular the crystalline orientation (002), of a second group IIIA metal nitride layer deposited directly on the first group IIIA metal nitride layer, in particular by magnetron sputtering, wherein the composition of the second group IIIA metal nitride layer is different from the composition of the first group IIIA metal nitride layer.

A first example, according to the invention, was prepared as follows in a magnetron sputtering coating line where the substrate is continuously transported through the different coating stations without stopping during deposition of the layers. For all deposition steps, the pressure was kept at values ranging from 0.1 to 99 mTorr.

On a 40 cm by 40 cm substrate of 4 mm thick soda lime glass, an amorphous 27 nm thick Zn₂SnO₄ film was deposited by magnetron sputtering from a mixed zinc-tin metal target in an atmosphere of Ar and O2 (80% of O2).

Then, a seed layer of undoped ZnO was deposited using magnetron sputtering of a Zn target in an atmosphere of Ar and O₂ (80% of O₂). The seed layer had a thickness of 7 nm.

Next, a layer of aluminum nitride was deposited directly on the seed layer by magnetron sputtering of an aluminum target in an atmosphere of Ar and N₂ (30% N₂). The aluminum nitride layer had a thickness of 30 nm. To reach this thickness, the substrate was moved 6 times through the same coating station.

A second, comparative, example was prepared by depositing the same aluminum nitride layer as for the first example without any seed layer, directly on a substrate of soda lime glass.

No heating was performed on any of the examples before after or during the deposition steps.

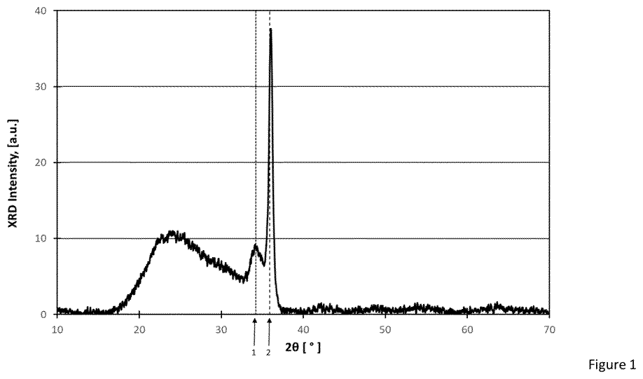

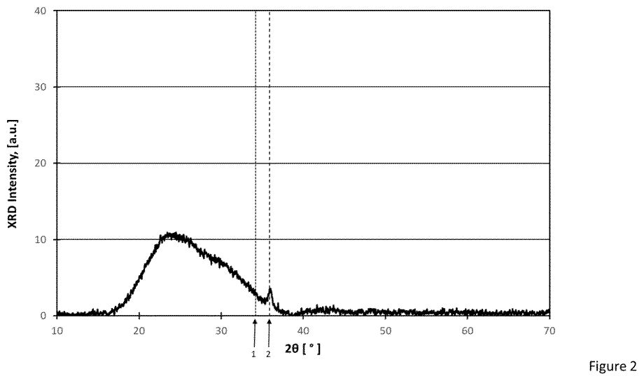

X-ray diffraction (XRD) measurements were performed, not in a grazing angle mode, on the prepared examples. The resulting XRD plots can be seen in FIG. 1, for example 1, and FIG. 2, for example 2. Generally, for AlN films, different diffraction peaks at 2θ values of 33.2°, 35.8°, 37.7°, 51.7°, 59.3°, 65.0°, and 71.0° are assigned to the (100), (002), (101), (102), (110), (103), and (112) planes of hexagonal AlN, respectively, based on the PDF card (no: 01-080-6097). Arrow (2) indicates the 2θ value for AlN (002). Arrow (1) indicates the 2θ value for ZnO (002).

Comparing FIG. 1 to FIG. 2, we can see that the deposition in example 1 of the aluminum nitride layer on the seed layer, very significantly increases the preferential (002) crystalline orientation, compared to the direct deposition on the substrate of example 2.

A similar result as in example 2 was obtained when the AlN film was deposited on a soda lime glass substrate provided with an amorphous 27 nm thick Zn₂SnO₄ film.

The deposition of the AlN film under 100% N₂ atmosphere was found to lead to comparable results as in examples 1 and 2.

The deposition processes of example 1 and 2 was repeated of substrates of plastic and metal. Also on these substrates, which in the present case were polycarbonate, Kapton and aluminum, when the aluminum nitride layer is deposited on a seed layer, the preferential (002) crystalline orientation is increased, compared to the direct deposition on the substrate.

1: A process for depositing group IIIA metal nitride layers comprising: providing a substrate; depositing by magnetron sputtering a seed layer comprising ZnO on the substrate; and depositing by magnetron sputtering a first group IIIA metal nitride layer directly on the seed layer.

2: The process according to claim 1, further comprising depositing by magnetron sputtering a second group IIIA metal nitride layer directly on the first group IIIA metal nitride layer, the second group IIIA metal nitride being different from the first group IIIA metal nitride film.

3: The process according claim 2, wherein the first and/or second group IIIA metal nitride layers have a preferred (002) orientation.

4: The process according to claim 1, wherein the seed layer has a thickness of at least 0.3 nm and/or of up to 250 nm.

5: The process according to claim 4, wherein the seed layer comprises up to 10 at % of a dopant selected from the group consisting of Al, Ga, B, and In.

6: The process according to claim 4, wherein the seed layer is deposited by magnetron sputtering a target selected from the group consisting of
a. a Zn metal target, optionally doped with Al, Ga, B, or In; and
b. a ceramic ZnO target, optionally doped with Al, Ga, B, or In.

7: The process according to claim 2, wherein the first and/or second group IIIA metal nitrides are selected from the group consisting of indium nitride, aluminum nitride, gallium nitride, boron nitride, or from a mixed nitride of two or more of indium nitride, aluminum nitride, gallium nitride, and boron nitride.

8: The process according to claim 2, wherein the first group IIIA metal nitride comprises a mixed nitride of indium and aluminum and the second group IIIA metal nitride comprises gallium nitride.

9: The process according to claim 2, wherein the thickness of the first and/or second group IIIA metal nitride layers is at least 10 nm.

10: The process according to claim 1, wherein the substrate is selected from the group consisting of crystalline Ge, crystalline Si, sapphire, a metal and glass.

11: The process according to claim 2, wherein no heating of the substrate is performed, prior to or during the deposition of the seed layer and/or first group IIIA metal nitride layer and/or second group IIIA metal nitride layer.

12: The process according to claim 2, further comprising, after depositing the first and/or second group IIIA metal nitride layers, heating of the substrate to at least 100° C.

13: The process according to claim 1, further comprising, before deposition of the seed layer, deposition of an amorphous layer, comprising a material selected from the group consisting of Zn₂SnO₄, Si₃N₄, SiO₂, titanium oxide, nitride of zirconium and silicon, oxide of titanium and zirconium.

14. A coated substrate comprising in sequence, starting from the substrate surface:
a seed layer comprising ZnO;
a first group IIIA metal nitride layer; and
optionally a second group IIIA metal nitride layer,
wherein the composition of the second group IIIA metal nitride layer is different from the first group IIIA metal nitride layer, and
wherein the first group IIIA metal nitride layer is in direct contact with the seed layer and has a preferred crystalline orientation (002) and
wherein the second group IIIA metal nitride layer is in direct contact with the seed layer and has a preferred crystalline orientation (002).

15: A method of increasing the crystallinity of the first group IIIA metal nitride layer in the coated substrate according to claim 14, comprising depositing the first group IIIA metal nitride layer directly onto the seed layer.

16: A method of increasing the crystallinity of the first group IIIA metal nitride layer and the crystallinity of the second group IIIA metal nitride layer in the coated substrate according to claim 14, comprising:
depositing the first group IIIA metal nitride layer directly onto the seed layer; and
depositing the second group IIIA metal nitride layer directly on the first group IIIA metal nitride layer,
wherein a composition of the second group IIIA metal nitride layer is different from a composition of the first group IIIA metal nitride layer.
